(19) United States
(12) Patent Application Publication
(10) Pub. No.: US 2006/0183030 A1
(43) Pub. Date: Aug. 17, 2006

(54) Photomask, method of generating mask pattern, and method of manufacturing semiconductor device

(75) Inventor: Shuji Nakao, Chiyoda-ku (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/350,123

(22) Filed: Feb. 9, 2006

(30) Foreign Application Priority Data
Feb. 14, 2005 (JP) 2005-036409

(51) Int. Cl. G06F 17/50; G03F 1/00; G03C 5/00

(52) U.S. Cl. 430/5; 716/19; 716/21; 430/322; 430/323; 430/324

(57) ABSTRACT

A photomask includes a pair of light-transmission opening patterns extending in parallel and each having a substantially identical line width with a center light-shielding linear portion extending linearly therebetween, and semi-transmissive regions arranged to sandwich the pair of light-transmission opening patterns from opposing sides in a direction of width. The semi-transmissive region serves as an in-phase semi-transmissive portion with such a characteristic that transmitted light is in phase with light transmitted through the light-transmission opening pattern. In addition, the semi-transmissive region includes patterns arranged at such a small pitch as not resolved by illumination of light.

### BACKGROUND OF THE INVENTION

1. Field of the Invention

The present invention relates to a photomask, a method of generating a mask pattern, and a method of manufacturing a semiconductor device.

2. Description of the Background Art

When a pair of linear opening portions isolated from other pattern and extending in parallel to each other is formed in a light-shielding film or in a halftone film on a photomask, if a width of the linear opening portion and an interval between the pair are appropriately selected, a phenomenon that a very thin dark line image (hereinafter, referred to as a “fine dark line image”) appears between two bright line images created by the two linear opening portions during projection exposure. It has been confirmed that this phenomenon is utilized to form a resist pattern of a width of approximately 40 nm by using KrF excimer laser (wavelength of 248 nm) as a light source.

Japanese Patent Laying-Open No. 2002-075823 discloses a technique to create fine dark line images by using a pair of linear opening portions isolated and extending in parallel. In addition, Japanese Patent Laying-Open Nos. 11-015130 and 11-288079 disclose related techniques.

According to the conventional technique, a region outside the pair of linear opening portions isolated on the mask serves as a light-shielding film or a halftone phase shift film. Therefore, the outside region becomes a dark region as dark as the fine dark line image created between two bright lines, and an unnecessary resist pattern remains in this region after development with exposure of one time. According to the conventional technique, in order to avoid remaining of the unnecessary resist pattern, it has been necessary to prepare another mask for double exposure so as to turn the outside region to a bright portion. As the double exposure step achieves low throughput per a unit time and requires two masks, it has been disadvantageous in terms of cost.

### SUMMARY OF THE INVENTION

An object of the present invention is to form a desired pattern with a single mask in exposure of one time.

In order to achieve the object above, a photomask according to the present invention includes a pair of light-transmission opening patterns extending in parallel and each having a substantially identical line width with a center light-shielding linear portion extending linearly therebetween, and semi-transmissive regions arranged to sandwich the pair of light-transmission opening patterns from opposing sides in a direction of width. The semi-transmissive region has such a characteristic that light transmitted through the semi-transmissive region is in phase with light transmitted through the light-transmission opening pattern. The semi-transmissive region is implemented by patterns arranged at such a small pitch as not resolved by projection exposure, so that transmitted light is attenuated to attain a semi-transmissive state, and is in phase with the light transmitted through the light-transmission opening pattern.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a photomask in Embodiment 1 of the present invention.

FIG. 2 is a partially enlarged plan view of a fine dark line image forming portion of the photomask in Embodiment 1 of the present invention.

FIG. 3 is a partially enlarged plan view of a variation of the photomask in Embodiment 1 of the present invention.

FIG. 4 is a graph showing distribution of relative intensity of an optical image created by the photomask in Embodiment 1 of the present invention.

FIG. 5 is a graph showing variation of a critical dimension CD obtained by using the photomask in Embodiment 1 of the present invention.

FIG. 6 is a plan view of a photomask in Embodiment 2 of the present invention.

FIG. 7 is a graph showing distribution of relative intensity of an optical image created by the photomask in Embodiment 2 of the present invention.

FIG. 8 is a graph showing variation of a critical dimension CD obtained by using the photomask in Embodiment 2 of the present invention.

FIG. 9 is a cross-sectional view of a photomask in Embodiment 3 of the present invention.

FIG. 10 illustrates a first step in a method of forming a pattern of a semiconductor device in Embodiment 4 of the present invention.

FIG. 11 illustrates a second step in the method of forming the pattern of the semiconductor device in Embodiment 4 of the present invention.

FIG. 12 illustrates a third step in the method of forming the pattern of the semiconductor device in Embodiment 4 of the present invention.

FIG. 13 illustrates first off-axis modified illumination that can be employed in the method of forming the pattern of the semiconductor device in Embodiment 4 of the present invention.

FIG. 14 illustrates second off-axis modified illumination that can be employed in the method of forming the pattern of the semiconductor device in Embodiment 4 of the present invention.

FIG. 15 illustrates third off-axis modified illumination that can be employed in the method of forming the pattern of the semiconductor device in Embodiment 4 of the present invention.

FIG. 16 shows a design pattern layout in Embodiments 5 to 9 of the present invention.

FIG. 17 is a diagram showing a light-shielding portion pattern in Embodiment 5 of the present invention.

FIG. 18 is a diagram showing a mask pattern in Embodiment 5 of the present invention.

FIG. 19 is a diagram showing a mask pattern inside an in-phase semi-transmissive portion in Embodiment 5 of the present invention.

FIG. 20 is a diagram showing a light-shielding portion pattern in Embodiment 6 of the present invention.

FIG. 21 is a diagram showing a mask pattern in Embodiment 6 of the present invention.

FIG. 22 is a diagram showing a mask pattern inside an in-phase semi-transmissive portion in Embodiment 6 of the present invention.

FIG. 23 is a diagram showing a light-shielding portion pattern in Embodiment 7 of the present invention.

FIG. 24 is a diagram showing a light-transmission opening pattern in Embodiment 7 of the present invention.

FIG. 25 is a diagram showing a mask pattern in Embodiment 7 of the present invention.

FIG. 26 is a diagram showing a light-shielding portion pattern in Embodiment 8 of the present invention.

FIG. 27 is a diagram showing a light-transmission opening pattern in Embodiment 8 of the present invention.

FIG. 28 is a diagram showing a mask pattern in Embodiment 8 of the present invention.

FIG. 29 is a diagram showing a light-shielding portion pattern in Embodiment 9 of the present invention.

FIG. 30 is a diagram showing a light-transmission opening pattern in Embodiment 9 of the present invention.

FIG. 31 is a diagram showing a mask pattern in Embodiment 9 of the present invention.

### DESCRIPTION OF THE PREFERRED EMBODIMENTS

### Embodiment 1

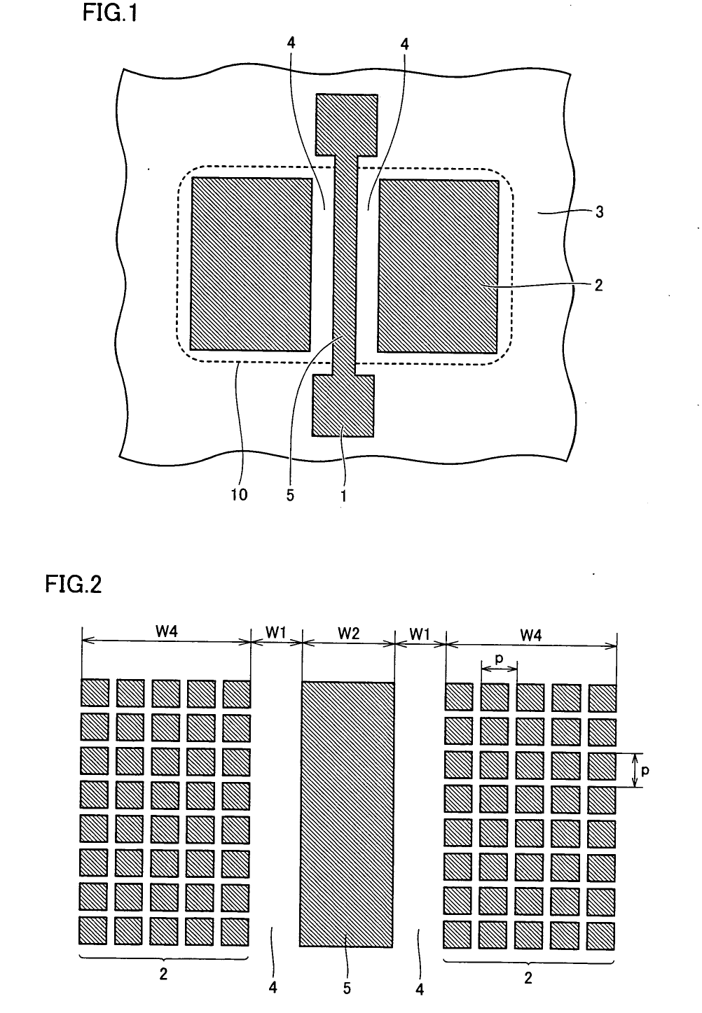

Referring to FIGS. 1 to 3, a photomask in Embodiment 1 of the present invention will be described. The photomask includes a quartz substrate and a Cr film formed to cover a main surface thereof and subsequently patterned. The photomask includes a fine dark line image forming portion 10 for forming a pattern of fine lines isolated on a resist film as shown in FIG. 1. The photomask has a light-shielding portion 1, an in-phase semi-transmissive portion 2, and a transmissive portion 3. Light-shielding portion 1 is formed with the Cr film and includes a center light-shielding linear portion 5. FIG. 2 shows enlarged fine dark line image forming portion 10 in FIG. 1. The photomask has a pair of light-transmission opening patterns 4 extending in parallel and each having a substantially identical line width with center light-shielding linear portion 5 extending linearly therebetween, and in-phase semi-transmissive portions 2 serving as semi-transmissive regions arranged to sandwich the pair of light-transmission opening patterns 4 from opposing sides in a direction of width.

Specifically, as shown in FIG. 2, in-phase semi-transmissive portion 2 serving as the semi-transmissive region is implemented by a set of fine patterns arranged at such a small pitch as not resolved by projection exposure. The fine pattern is not particularly limited, provided that the fine patterns are arranged at such a small pitch as not resolved by projection exposure. Preferably, the semi-transmissive region is implemented in such a manner that basic patterns are repeated at a pitch p which satisfies relation of p<0.5×λ/NA, where λ represents a wavelength of projected light and NA represents a numerical aperture of the semi-transmissive region. FIG. 2 shows an example in which the basic pattern satisfying the above-described condition is implemented by a square light-shielding portion. In this example, the square light-shielding portion is formed by patterning the Cr film formed on the quartz substrate, as in the case of center light-shielding linear portion 5. Namely, the semi-transmissive region is formed by an array of light-shielding pad patterns at small pitch p. As pitch p is small enough for diffracted light except for zero-order diffracted light to pass through projection optical system, an effect is such that light is simply attenuated. Accordingly, the light transmitted through the semi-transmissive region is attenuated and in phase with the light transmitted through light-transmission opening pattern 4. Preferably, in-phase semi-transmissive portion 2 serving as the semi-transmissive region is adjusted to have transmittance of light from at least 10% to at most 50%.

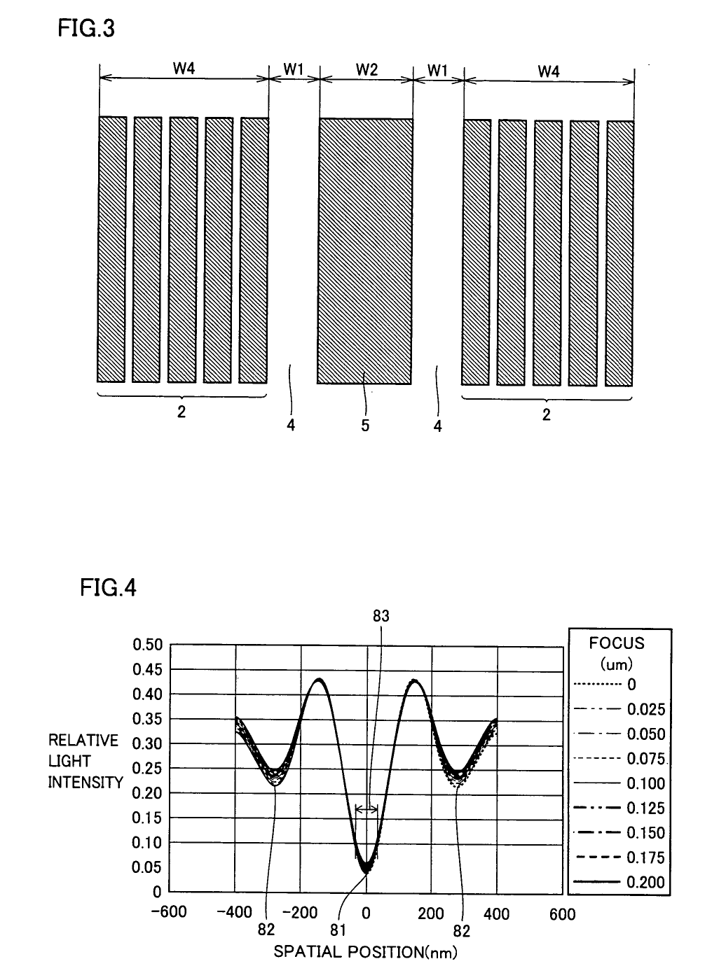

Though FIG. 2 shows the basic pattern in the semi-transmissive region in a square shape, the basic pattern is not limited to square and may be substantially rectangular or linear. FIG. 3 shows an example in which the basic pattern is in a linear shape. In employing a square basic pattern, the semi-transmissive region is not limited to such arrangement that small square light-shielding portions are arranged in the transmissive portion, but the arrangement may be such that small square opening portions are arranged in the light-shielding portion.

Referring again to FIG. 2, it is center light-shielding linear portion 5 having a line width W2 that forms a pattern of fine lines. Though depending on a dimension of a resist pattern to be formed or exposure dose, preferably, line width W2 satisfies relation of W2>0.25×λ/NA, where λ represents an exposure light wavelength and NA represents a numerical aperture of projection exposure optical system. Light-transmission opening pattern 4 (also referred to as a “bright line portion”) arranged on each side of center light-shielding linear portion 5 has a line width W1. Preferably, line width W1 satisfies relation of 0.25×λ/NA<W1<0.75×λ/NA.

In addition, in-phase semi-transmissive portions 2 serving as the semi-transmissive region having the above-described characteristic are arranged on both sides of the pair of light-transmission opening patterns 4 respectively, and in-phase semi-transmissive portions 2 has a width W4. Preferably, line width W4 satisfies relation of W4>0.75×λ/NA.

Intensity distribution of optical images, when a photomask in a pattern arrangement satisfying the above-described condition, that is, W1=170 nm, W2=85 nm and W4=400 nm, was illuminated with quadrupole illumination in which σout/in=0.80/0.60 and an image was formed by a projection exposure system in which wavelength was set to 248 nm and numerical aperture NA=0.85, was obtained through calculation. FIG. 4 is a graph for the optical images, in which the ordinate represents relative light intensity while the abscissa represents a distance from the center of the pattern to the left and right. The graph shows distribution of relative light intensity with varied focus. Here, “focus” means a spatial distance from a focal point with respect to a direction perpendicular to an image forming plane.

It can be seen from the graph in FIG. 4 that a sharp dark line image is formed in a position corresponding to center light-shielding linear portion 5 by means of the photomask and that light intensity at a darkest portion 81 in the dark line image hardly varies in spite of variation in focus. In addition, in the region corresponding to in-phase semi-transmissive portion 2 serving as the semi-transmissive region of the photomask, light intensity is lowest in a relative minimum portion 82, whereas light intensity in relative minimum portion 82 is four times or more as great as light intensity in darkest portion 81 in the dark line image. Therefore, exposure dose is appropriately selected taking into consideration difference between light intensity in darkest portion 81 and light intensity in relative minimum portion 82, so that one resist pattern can be formed around darkest portion 81 while the resist does not remain in other region.

An image quality condition required for resolution of the resist pattern is that exposure energy at a pattern edge is approximately twice or more as great as the exposure energy at the darkest point. In this example, as shown in FIG. 4, relative light intensity at darkest portion 81 is approximately 0.05, which means that relative light intensity of 0.1 should be set as the minimum relative light intensity required for resolution at the pattern edge. Here, relative light intensity refers to light intensity standardized by assuming as 1, intensity of light incident on the center of an opening pattern sufficiently larger than a wavelength. In addition, if a type and a thickness of the resist are determined, exposure energy at the resist pattern edge (the product of the exposure dose defined below and relative light intensity at the resist pattern edge) is substantially constant, irrespective of the pattern. Therefore, when the resist pattern edge is formed on a contour line attaining relative light intensity of Is, exposure energy at the opening sufficiently larger than the wavelength is 1/Is times as great as the exposure energy at the resist pattern edge. In contrast, in an attempt to form a resist pattern substantially coinciding the contour line attaining relative light intensity of Is, exposure energy at the center of the opening much larger than the wavelength should be set to 1/Is times as great as the exposure energy at the resist pattern edge. Normally, magnitude of an amount of energy incident on the resist at the time of exposure in an exposure apparatus is defined in terms of incident energy per a unit area in an opening pattern sufficiently larger than a wavelength, and referred to as “exposure dose”. Namely, the resist pattern substantially coinciding the contour line attaining relative intensity of Is in optical image intensity distribution is obtained by employing exposure dose obtained as a result of division of the exposure energy at the resist pattern edge by relative light intensity Is.

For example, relative light intensity at the pattern edge of 0.1 means that the exposure energy supplied to a wide opening portion outside fine dark line image forming portion 10 is 1/0.1=10 times as great as the exposure energy at the pattern edge. In contrast, in order to set a position where relative light intensity is 0.1 as the pattern edge for forming a minimum resolution pattern, the exposure dose should be set to 10 times as great as the exposure energy at the pattern edge. Here, it can be seen that a pattern dimension CD, which is a width of a section 83 in FIG. 4, is smaller than 100 nm.

FIG. 5 shows variation in pattern dimension CD with varied light intensity Is at the pattern edge, that is, with varied exposure dose. In FIG. 5, the abscissa represents the focus while the ordinate represents pattern dimension CD. For example, it can be seen that, when Is is set to 0.130, a line pattern having a width of approximately 90 nm is formed at a depth of focus of at least 0.4 μm. This performance is comparable to a conventional method in which a pattern is formed in double exposure.

As described above, according to the present invention, fine line pattern formation that has conventionally required double exposure can be achieved in exposure of one time and significant reduction in manufacturing cost is achieved. In addition, in terms of process design as well, it is no longer necessary to consider fluctuation in a pattern dimension caused by a slight additional dose due to double exposure and what is called optical proximity correction (OPC) is remarkably simplified.

In the present embodiment, excellent focus characteristic can be obtained by satisfying the relation of 0.25×λ/NA<W1<0.75×λ/NA. In the present embodiment, the relation of W2>0.25×λ/NA is satisfied so that too bright an image can be prevented and the fine line pattern can be formed in one exposure. In the present embodiment, the relation of W4>0.75×λ/NA is satisfied so that a dark line image of excellent characteristic can be created between a pair of bright lines, without the pair of bright lines being affected by other bright line portion.

Preferably, relation of W3>0.75×(λ/NA) is satisfied, where W3 represents an interval between light-transmission opening patterns 4 and adjacent another pair of light-transmission opening patterns. If this relation is not satisfied, light-transmission opening patterns 4 are too close to another pair of light-transmission opening patterns and an excellent dark line image cannot be created between the bright line portions.

Preferably, the light-transmission opening pattern has a length L which satisfies relation of L>1.3×(λ/NA). This is because at least such a length is necessary for creating an excellent dark line image between a pair of bright line portions.

### Embodiment 2

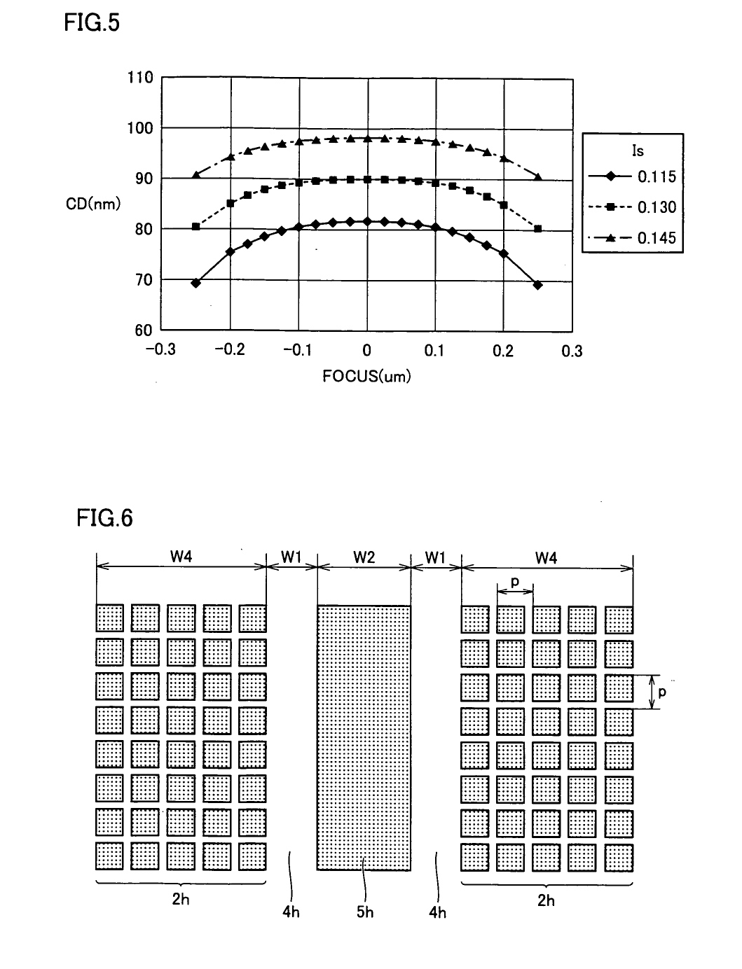

Referring to FIG. 6, a photomask in Embodiment 2 of the present invention will be described. The photomask includes a quartz substrate and an MoSi oxinitride film formed to cover a main surface thereof and subsequently patterned. The photomask includes a fine dark line image forming portion for forming an isolated resist pattern of fine dark lines. Positional relation of these portions is the same as shown in FIG. 1. FIG. 6 shows an enlarged view of the fine dark line image forming portion of the photomask. Preferable conditions for W1, W2 and W4 in FIG. 6 are the same as those described in Embodiment 1. The semi-transmissive region has transmittance in a range from at least 10% to at most 50%.

The MoSi oxinitride film formed on the main surface of the quartz-substrate in the photomask has light transmittance of 6%, and it is set such that light transmitted through the MoSi oxinitride film has a phase shifted by 180° with respect to light transmitted through a portion where the MoSi oxinitride film does not exist. The setting is made by appropriately adjusting a thickness of the MoSi oxinitride film. Patterns shown in FIG. 6 are all formed by patterning the MoSi oxinitride film. The photomask has a pair of light-transmission opening patterns 4h extending in parallel and each having a substantially identical line width on the left and right, with a center light-shielding linear portion 5h extending linearly therebetween, and in-phase semi-transmissive portions 2h serving as semi-transmissive regions arranged to sandwich the pair of light-transmission opening patterns 4h from opposing sides in a direction of width. In-phase semi-transmissive portion 2h serving as the semi-transmissive region is formed by an array of pad patterns at pitch p. As pitch p is small enough for diffracted light except for zero-order diffracted light to pass through a projection optical system, the light is effectively attenuated. In addition, variation in the phase of the transmitted light can be avoided by adjusting the pad size, and actually variation in the phase is avoided. In the present embodiment, pitch p between the pads is set to 100 nm, and the pad has a square shape and a size of 70 nm×70 nm.

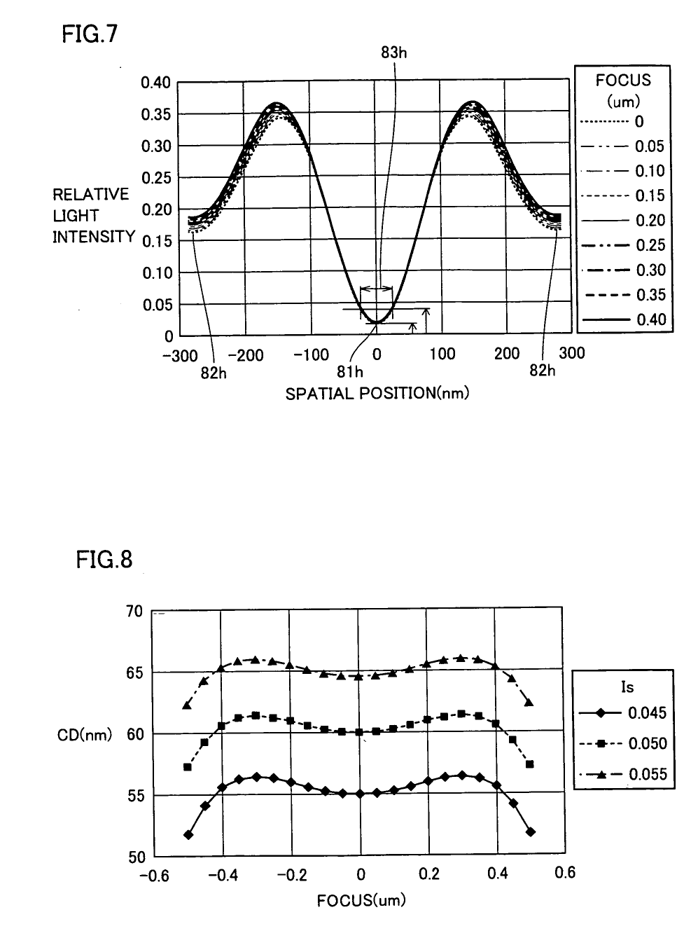

Intensity distribution of optical images, when a photomask in a pattern arrangement satisfying the above-described condition, that is, W1=170 nm, W2=100 nm and W4=300 nm, was illuminated with quadrupole illumination in which σout/in=0.80/0.60 and an image was formed by a projection exposure system in which wavelength was set to 248 nm and numerical aperture NA=0.85, was obtained through calculation. FIG. 7 is a graph, in which the ordinate represents relative light intensity of the optical image while the abscissa represents a distance from the center of the pattern to the left and right, as in FIG. 4. The graph shows distribution of relative light intensity with varied focus.

It can be seen from the graph in FIG. 7 that a sharp dark line image is formed in a position corresponding to center light-shielding linear portion 5h by means of the photomask and that light intensity at a darkest portion 81h in the dark line image hardly varies in spite of variation in focus. In addition, in the region corresponding to in-phase semi-transmissive portion 2h serving as the semi-transmissive region of the photomask, light intensity is lowest in a relative minimum portion 82h, whereas light intensity in relative minimum portion 82h is eight times or more as great as light intensity in darkest portion 81h in the dark line image. Therefore, exposure dose is appropriately selected taking into consideration difference between light intensity in darkest portion 81h and light intensity in relative minimum portion 82h, so that one resist pattern can be formed around darkest portion 81h while the resist does not remain in other region. Therefore, exposure can be completed with a single mask.

An image quality condition required for resolution of the pattern is that exposure energy at a pattern edge is approximately twice or more as great as the exposure energy at the darkest point. In FIG. 7, relative light intensity of 0.05 is the minimum light intensity for resolution at the pattern edge. If a type and a thickness of the resist are determined, exposure energy at the pattern edge is substantially constant, irrespective of the pattern. The light intensity at the pattern edge of 0.05 means that the exposure energy, that is, exposure dose, supplied to a wide opening portion outside the fine dark line image forming portion is 1/0.05=20 times as great as the exposure energy at the pattern edge. Accordingly, in order for the light intensity at the resist pattern edge to be of magnitude as great as necessary for desolution of the resist, the exposure dose should be set to 20 times or less as great as the exposure. energy at the resist pattern edge. Here, the minimum resolution pattern is obtained when the exposure dose is set to 20 times as great as the exposure energy at the resist pattern edge. Here, pattern dimension CD is as large as a width of a section 83h obtained at relative light intensity twice as high as relative light intensity at darkest portion 81h in FIG. 7, that is, as large as 60 nm.

FIG. 8 shows variation in pattern dimension CD with several values for light intensity Is at the pattern edge, that is, for exposure dose. In FIG. 8, it can be seen that, for example when Is is set to 0.050, a line pattern having a width of approximately 60 nm is formed at a depth of focus of at least 0.4 μm. This performance is comparable to or superior to a conventional method employing double exposure.

### Embodiment 3

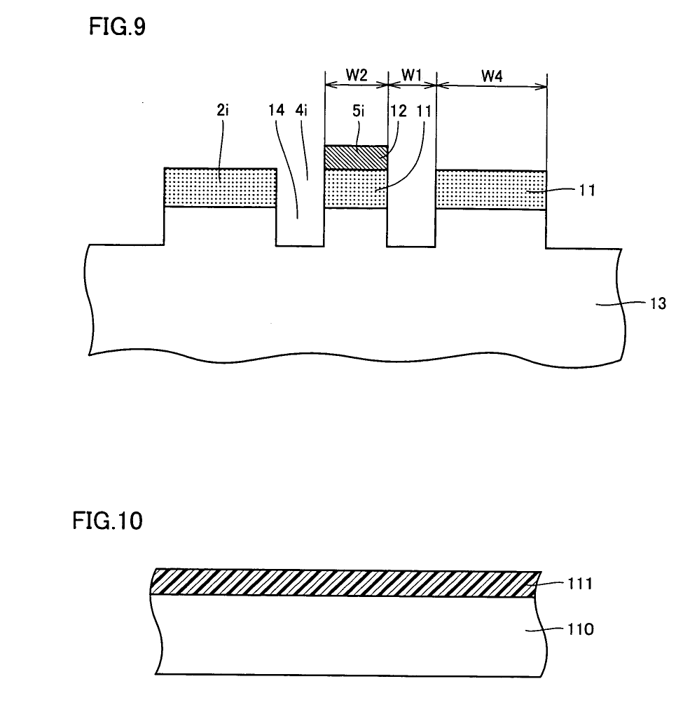

Referring to FIG. 9, a photomask in Embodiment 3 of the present invention will be described. The photomask includes a pair of light-transmission opening patterns 4i extending in parallel and each having a substantially identical line width on the left and right with a center light-shielding linear portion 5i serving as the light-shielding portion extending linearly therebetween, and in-phase semi-transmissive portions 2i serving as semi-transmissive regions arranged to sandwich the pair of light-transmission opening patterns 4i from opposing sides in a direction of width. Light-transmission opening patterns 4i and the semi-transmissive regions are provided on a transparent substrate 13. Light-transmission opening pattern 4i is implemented as a recessed portion 14 formed in a surface of transparent substrate 13. The semi-transmissive region is structured such that the surface of transparent substrate 13 is covered with a halftone phase shift film 11 implemented by the MoSi oxinitride film. A thickness and a material for halftone phase shift film 11 are determined such that exposure light transmitted through the film is opposite in phase with exposure light transmitted through a transmissive opening pattern where the film is not present. A depth of recessed portion 14 satisfies such relation that light transmitted through the semi-transmissive region is in phase with the light transmitted through light-transmission opening pattern 4i.

Center light-shielding linear portion 5i has line width W2. Center light-shielding linear portion 5i is formed by stacking, successively from the bottom, halftone phase shift film 11 implemented by the MoSi oxinitride film and a complete light-shield film 12 composed of Cr. Though depending on a dimension of a resist pattern to be formed or exposure dose, desirably, line width W2 satisfies relation of W2>0.25×λ/NA, where λ represents an exposure light wavelength and NA represents a numerical aperture of projection exposure optical system.

Light-transmission opening pattern 4i has a line width W1 satisfying relation of 0.25×λ/NA<W1<0.75×λ/NA. In-phase semi-transmissive portion 2i serving as the semi-transmissive region is arranged to have line width W4. In-phase semi-transmissive portion 2i is structured such that halftone phase shift film 11 is formed on transparent substrate 13. Desirably, halftone phase shift film 11 has transmittance in a range from 10 to 50%, and the transmittance is set to 20% in this example. Further, line width W4 preferably satisfies relation of W4>0.75×λ/NA.

As the photomask in the present embodiment has an optical configuration exactly the same as that in Embodiment 1, intensity distribution of the optical image is the same as shown in FIG. 4 and variation characteristic of pattern dimension CD in accordance with the focus is the same as shown in FIG. 5. An effect similar to that in Embodiments 1 and 2 can be obtained also in the present embodiment.

In the present embodiment, a structure obtained by stacking halftone phase shift film 11 on transparent substrate 13 is adopted as in-phase semi-transmissive portion 2i. Therefore, as compared with Embodiments 1 and 2 requiring such fine patterns as not resolved by projection exposure, comparable performance can be achieved solely with patterns having a large dimension. In addition, it is not that basic patterns repeated at a small pitch are used as in-phase semi-transmissive portion 2i. Therefore, even if a two-dimensional shape of in-phase semi-transmissive portion 2i is too complicated to express with simple rectangles, in-phase semi-transmissive portion 2i can be arranged freely, without forcibly dividing the pattern into repeated basic patterns.

The effect resulted from preferable conditions of W1, W2, W3, and W4 in Embodiments 2 and 3 is also the same as described in Embodiment 1.

### Embodiment 4

Referring to FIGS. 10 to 12, a method of forming a pattern of a semiconductor device in Embodiment 4 of the present invention will be described. As shown in FIG. 10, a photoresist layer 111 is formed in advance on a surface of an object 110. For the sake of convenience in description, object 110 is shown as if it is implemented as a single layer, however, object 110 is normally implemented by some kind of a substrate carrying a layer to be patterned on a top surface. Though FIG. 10 does not show specifically, the layer to be patterned may be, for example, a conductive layer.

As shown in FIG. 11, “the method of forming a pattern of a semiconductor device” in the present embodiment includes the step of partially exposing photoresist layer 111 to light by irradiating photoresist layer 111 formed in advance on the surface of object 110 through the photomask described in any one of Embodiments 1 to 3 and projecting a desired pattern. In FIG. 11, the light is emitted, for example, through the photomask described in Embodiment 1. Therefore, this photomask is implemented by Cr film 114 formed on the surface of quartz substrate 113.

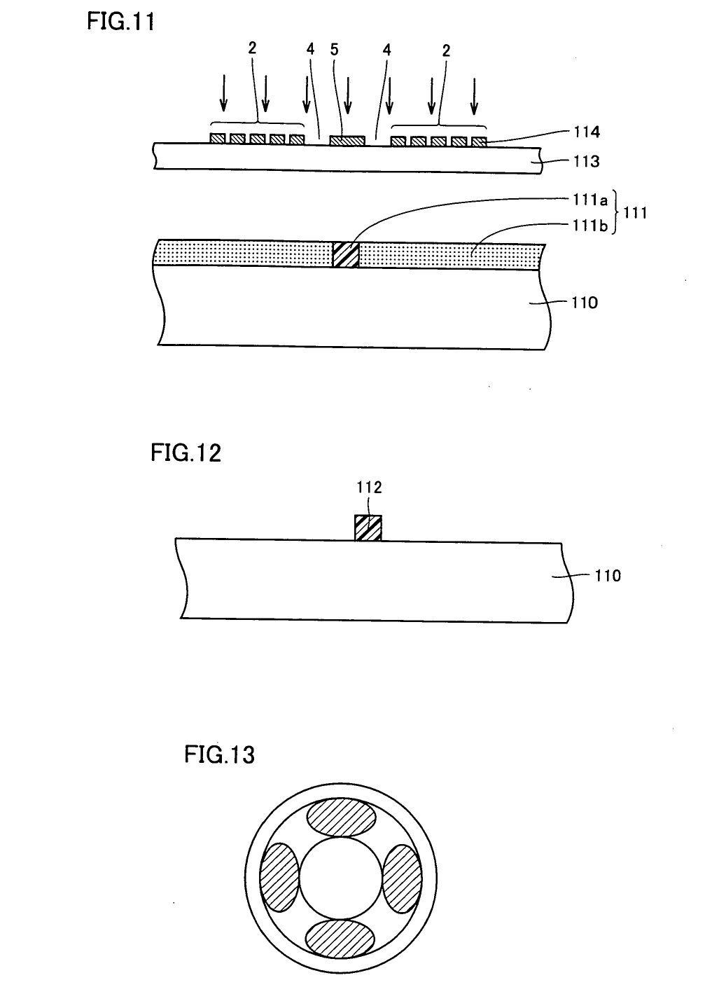

As a result of performing the exposing step, a fine dark line image is satisfactorily created in a region corresponding to center light-shielding linear portion 5 between the pair of light-transmission opening patterns 4, and the photoresist layer in other region can sufficiently be exposed to light. Consequently, as shown in FIG. 11, an unexposed portion 111a remains in the region corresponding to center light-shielding linear portion 5, whereas other region in photoresist layer 111 turns to an already-exposed portion 111b. Thereafter, as a result of development, linear pattern 112 formed with the photoresist can remain like a line with a small width, as shown in FIG. 12. Namely, exposure can be completed solely with a single mask, without using two masks. When fine linear patterns 112 obtained in the above-described manner are used for etching or the like, a fine pattern of a conductive layer or the like can be formed.

In the exposing step shown in FIG. 11, preferably, energy of light irradiating a main opening portion of the photomask, that is, an opening portion sufficiently larger than the wavelength, is of magnitude at least three times to at most twenty times as great as exposure energy to turn photoresist layer 111 from soluble to insoluble in a developer or exposure energy to turn photoresist layer 111 from insoluble to soluble in the developer. Here, a width of the opening portion is 10 times or more as great as the exposure light wavelength. If light is emitted with such energy, a region other than the center linear region can correctly be exposed.

In the exposing step shown in FIG. 11, preferably, off-axis illumination is employed, in which relation of 0.5<(sin θ)/(NAₒ×R)<0.9 is satisfied, where θ represents an incident angle of illumination light on the photomask, NAₒ represents a numerical aperture of a projection optical system, and 1/R (R>1) represents a reduction projection scale. In this manner, focus characteristic is improved and finer patterns can be formed. Preferably, the off-axis illumination here is realized by crosspole illumination in which a direction of incidence is in parallel to X, Y coordinate axes of the photomask, as shown in FIG. 13. A hatched area in FIG. 13 indicates a range of illumination. Such illumination is advantageous in forming a pattern of a semiconductor device in which linear patterns often extend in an oblique direction at an angle of 45° with respect to X and Y axes.

Alternatively, the off-axis illumination is preferably realized by quadrupole illumination in which a direction of incidence is at an angle of 45° to X, Y coordinate axes of the photomask, as shown in FIG. 14. Such illumination is advantageous in forming a pattern of a semiconductor device in which linear patterns often extend in parallel to X and Y axes.

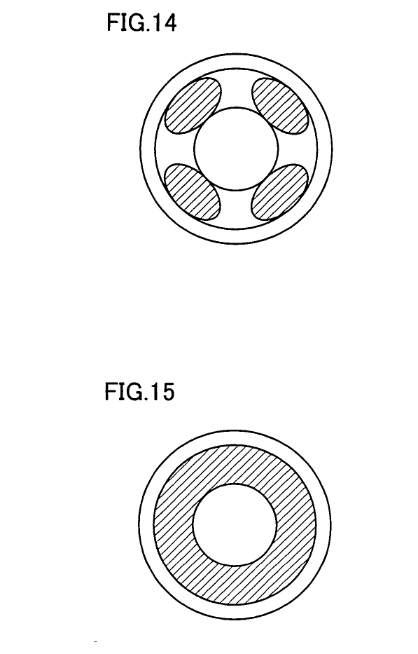

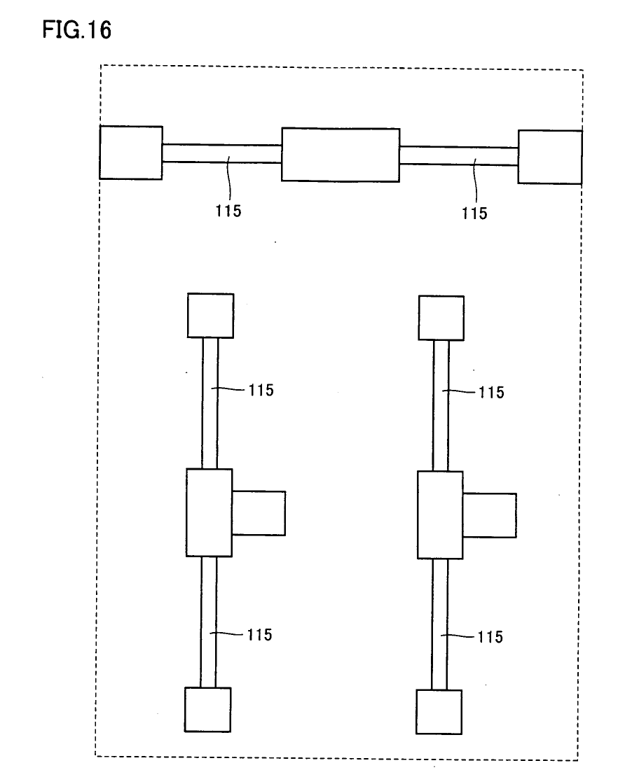

Alternatively, the off-axis illumination is preferably realized by annular illumination in which light enters a plane of the photomask isotropically around 360°, as shown in FIG. 15. Incidence of light becomes isotropic by using such illumination, and such illumination can generally be used for various patterns.

Though the method of forming a pattern of a semiconductor device has been described in the present embodiment, the present invention can be directed to a method of manufacturing a semiconductor device. The method of manufacturing a semiconductor device in the present embodiment includes not only the “exposing step” as described above but also the steps of developing the exposed photoresist layer so as to pattern the photoresist layer, and etching the object using the patterned photoresist layer as a mask, to form a linear pattern.

### Embodiment 5

Referring to FIGS. 1, 2, 12, and 16-19, a method of generating a mask pattern in Embodiment 5 of the present invention will be described. FIG. 16 shows a design pattern layout required in terms of device design. As shown in FIG. 16, the design pattern layout in this example includes a fine isolated linear portion 115 that should be formed by applying the technique shown in Embodiments 1 to 3 and a portion other than fine isolated linear portion 115 that has a large dimension and does not necessarily require application of the technique shown in Embodiments 1 to 3. Fine isolated linear portion 115 corresponds to linear pattern 112 shown in FIG. 12.

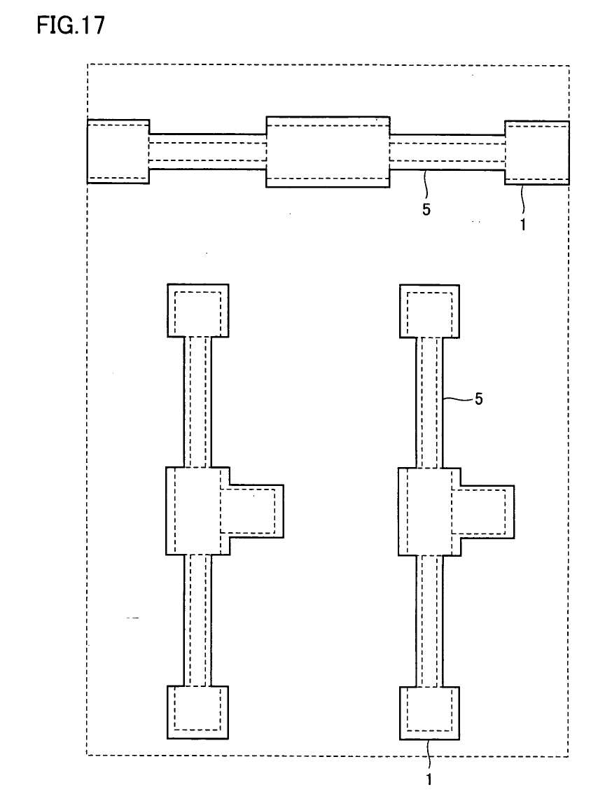

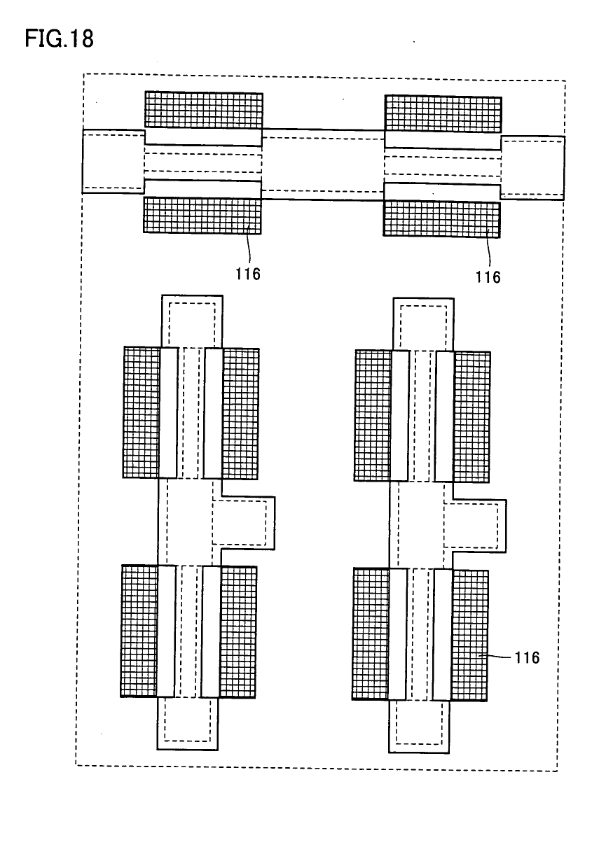

As a method of generating a mask pattern in the present embodiment, a method of generating a mask pattern when the technique in Embodiment 1 is applied will be described. Solely a fine linear geometric portion is extracted from the design pattern layout. A line width of the extracted portion is made larger to line width W2, and a geometry for center light-shielding linear portion 5 required for forming fine line patterns is created. Necessary resizing (dimension change) is performed also for the portion other than the fine linear geometric portion in the design pattern layout. Through the graphics processing above, light-shielding portion 1 in a mask is generated as shown in FIG. 17. Light-shielding portion 1 and center light-shielding linear portion 5 correspond to those shown in FIG. 1 according to the technique in Embodiment 1, respectively.

Thereafter, a rectangular region 116 having a length substantially equal to center light-shielding linear portion 5 and a width W4 in Embodiment 1 is created as a mask pattern corresponding to in-phase semi-transmissive portion 2 (see FIG. 2) in Embodiment 1. Then, rectangular regions 116 are arranged on opposing sides of center light-shielding linear portion 5 in a direction of width in parallel thereto, at a distance of W1 from the edge of center light-shielding linear portion 5, the distance being equal to a width of light-transmission opening pattern 4 in Embodiment 1.

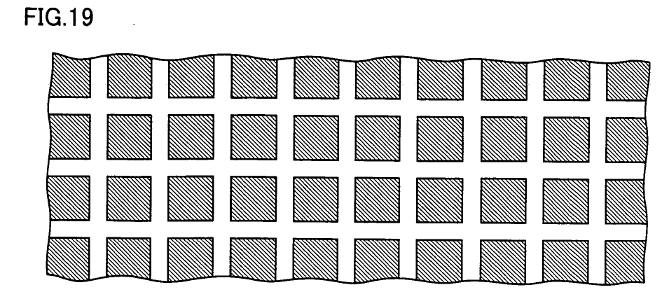

A mask pattern inside rectangular region 116 in FIG. 18 will now be described. FIG. 19 is an enlarged view of the pattern inside rectangular region 116. Rectangular region 116 is implemented in such a manner that rectangular light-shielding portions are arranged in a grid at such a small pitch as not allowing resolution by applied projection exposure system, as described in Embodiment 1.

The mask pattern (see FIG. 18) for applying the technique in Embodiment 1 is generated by generating and arranging the patterns that implement the mask, in accordance with the above-described procedure. It is noted that the portion other than the pattern implementing the aforementioned mask serves as a light-transmissive portion having a light-shielding film removed.

After the mask pattern is generated as described above, optical proximity correction (OPC) software, which is a common measure in the art, is used for fine adjustment of a position of a mask pattern edge.

As the method of generating the mask pattern in the present embodiment is carried out in the above-described manner, the mask pattern can automatically be generated from the design pattern layout of the device by using standard CAD software for layout design. Therefore, it is not necessary to manually generate the mask pattern and significant reduction in cost necessary for generating the mask pattern can be achieved.

### Embodiment 6

Referring to FIGS. 1, 6, 12, 16, and 20-22, a method of generating a mask pattern in Embodiment 6 of the present invention will be described. FIG. 16 shows a design pattern layout required in terms of device design. As shown in FIG. 16, the design pattern layout in this example includes fine isolated linear portion 115 that should be formed by applying the technique shown in Embodiments 1 to 3 and a portion other than fine isolated linear portion 115 that has a large dimension and does not necessarily require application of the technique shown in Embodiments 1 to 3. Fine isolated linear portion 115 corresponds to linear pattern 112 shown in FIG. 12.

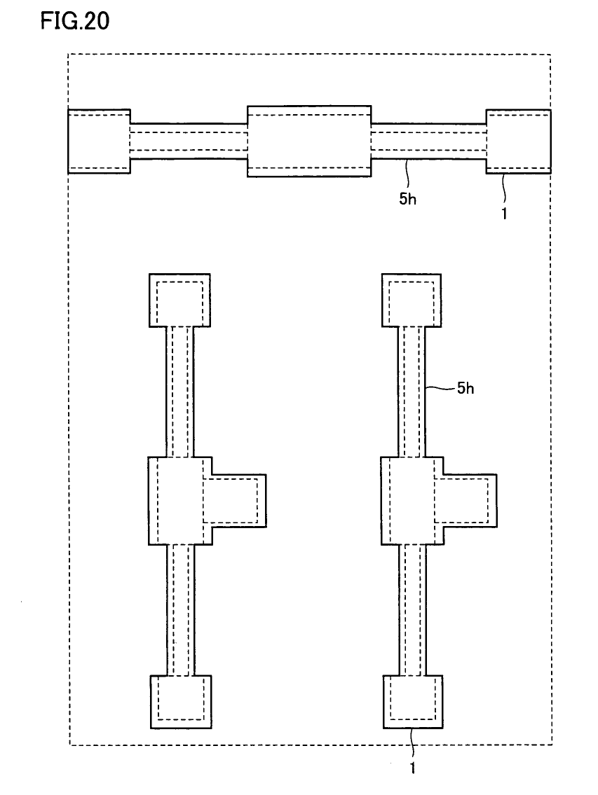

As a method of generating a mask pattern in the present embodiment, a method of generating a mask pattern when the technique in Embodiment 2 is applied will be described. Solely a fine linear geometric portion is extracted from the design pattern layout. A line width of the extracted portion is made larger to line width W2, and a geometry for center light-shielding linear portion 5h required for forming fine line patterns is created. Necessary resizing (dimension change) is performed also for the portion other than the fine linear geometric portion in the design pattern layout. Through the graphics processing above, a light-shielding pattern in a mask is generated as shown in FIG. 20. Center light-shielding linear portion 5h corresponds to that shown in FIG. 6 according to the technique in Embodiment 2.

Thereafter, a rectangular region 116h having a length substantially equal to center light-shielding linear portion 5h and a width W4 in Embodiment 2 is created as a mask pattern corresponding to in-phase semi-transmissive portion 2h (see FIG. 6) in Embodiment 2. Then, rectangular regions 116h are arranged on opposing sides of center light-shielding linear portion 5h in a direction of width in parallel thereto, at a distance of W1 from the edge of center light-shielding linear portion 5h, the distance being equal to a width of light-transmission opening pattern 4h in Embodiment 2.

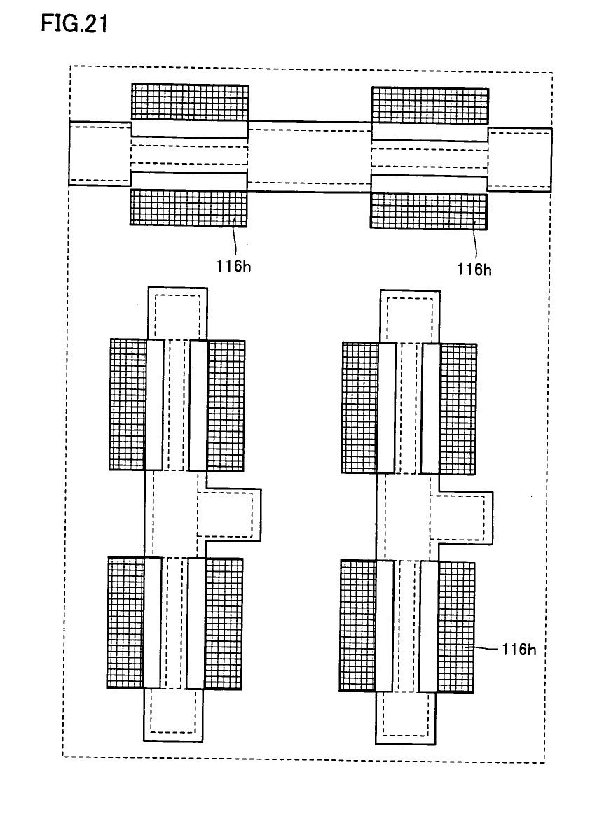

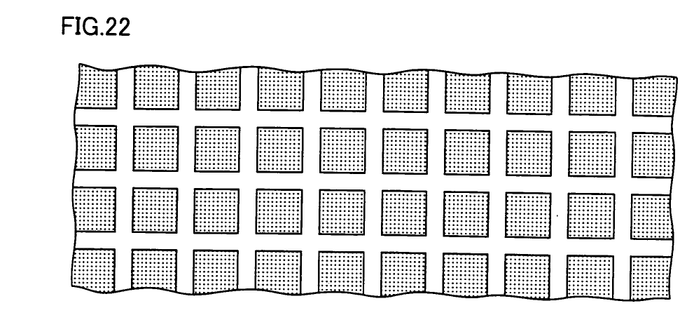

A mask pattern inside rectangular region 116h in FIG. 21 will now be described. FIG. 22 is an enlarged view of the pattern inside rectangular region 116h. Rectangular region 116h is implemented in such a manner that rectangular halftone phase shift patterns are arranged in a grid at such a small pitch as not allowing resolution by applied projection exposure system, as described in Embodiment 2.

The mask pattern (see FIG. 21) for applying the technique in Embodiment 2 is generated by generating and arranging the patterns that implement the mask, in accordance with the above-described procedure. It is noted that the portion other than the pattern implementing the aforementioned mask serves as a light-transmissive portion having a halftone phase shift film removed.

After the mask pattern is generated as described above, optical proximity correction (OPC) software, which is a common measure in the art, is used for fine adjustment of a position of a mask pattern edge.

As the method of generating the mask pattern in the present embodiment is carried out in the above-described manner, the mask pattern can automatically be generated from the design pattern layout of the device by using standard CAD software for layout design. Therefore, it is not necessary to manually generate the mask pattern and significant reduction in cost necessary for generating the mask pattern can be achieved.

### Embodiment 7

Referring to FIGS. 1, 2, 12, 16, and 23-25, a method of generating a mask pattern in Embodiment 7 of the present invention will be described. FIG. 16 shows a design pattern layout required in terms of device design. As shown in FIG. 16, the design pattern layout in this example includes fine isolated linear portion 115 that should be formed by applying the technique shown in Embodiments 1 to 3 and a portion other than fine isolated linear portion 115 that has a large dimension and does not necessarily require application of the technique shown in Embodiments 1 to 3. Fine isolated linear portion 115 corresponds to linear pattern 112 shown in FIG. 12.

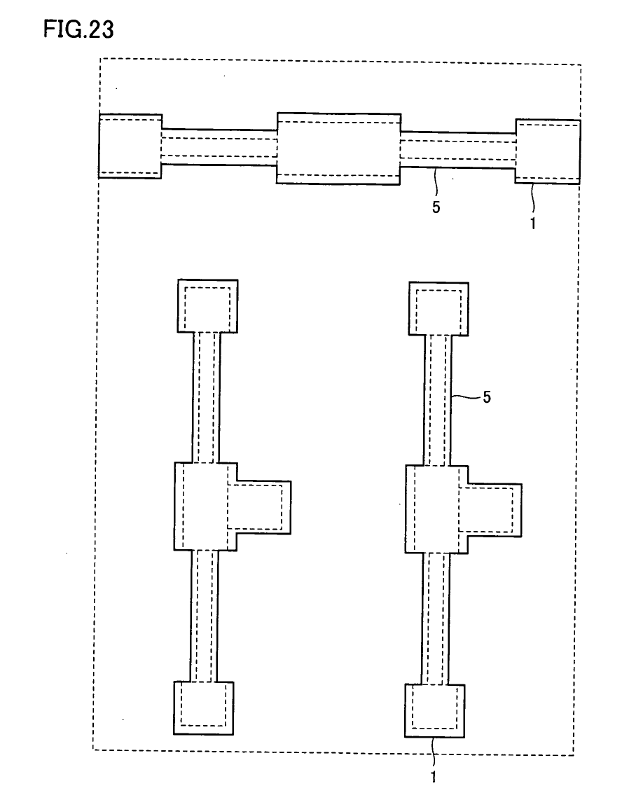

As a method of generating a mask pattern in the present embodiment, a method of generating a mask pattern different from that in Embodiment 5 when the technique in Embodiment 1 is applied will be described. Solely a fine linear geometric portion is extracted from the design pattern layout. A line width of the extracted portion is made larger to line width W2, and a geometry for center light-shielding linear portion 5 required for forming fine line patterns is created. Necessary resizing (dimension change) is performed also for the portion other than the fine linear geometric portion in the design pattern layout. Through the graphics processing above, light-shielding portion 1 in a mask is generated as shown in FIG. 23. Light-shielding portion 1 and center light-shielding linear portion 5 correspond to those shown in FIG. 1 according to the technique in Embodiment 1, respectively.

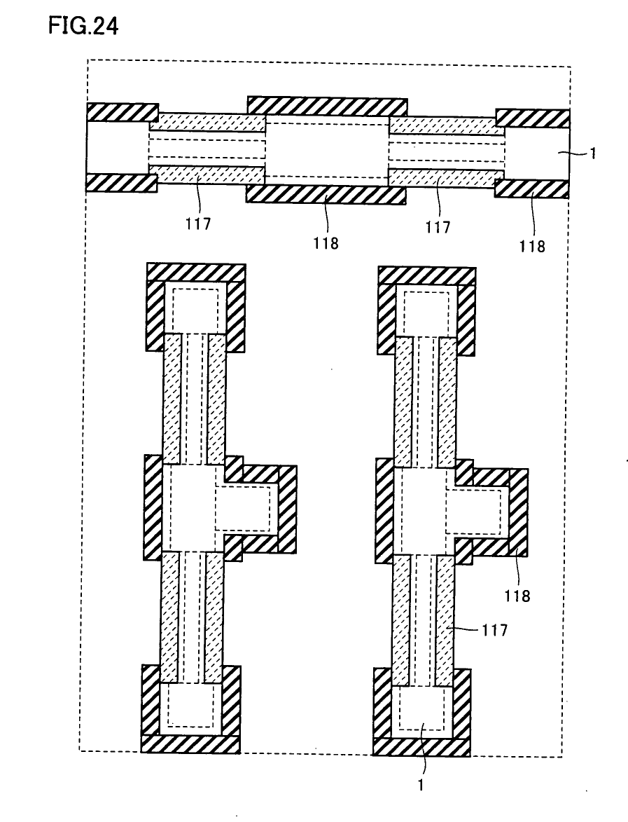

Thereafter, a linear pattern 117 having a length substantially equal to center light-shielding linear portion 5 and a width W1 in Embodiment 1 is created as a mask pattern corresponding to a pair of light-transmission opening patterns 4 (see FIG. 2) according to the technique in Embodiment 1. Then, a pattern 118 having a width close to W1 is arranged on an outer perimeter of a light-shielding geometry other than the fine linear geometric portion. The mask pattern shown in FIG. 24 is thus obtained.

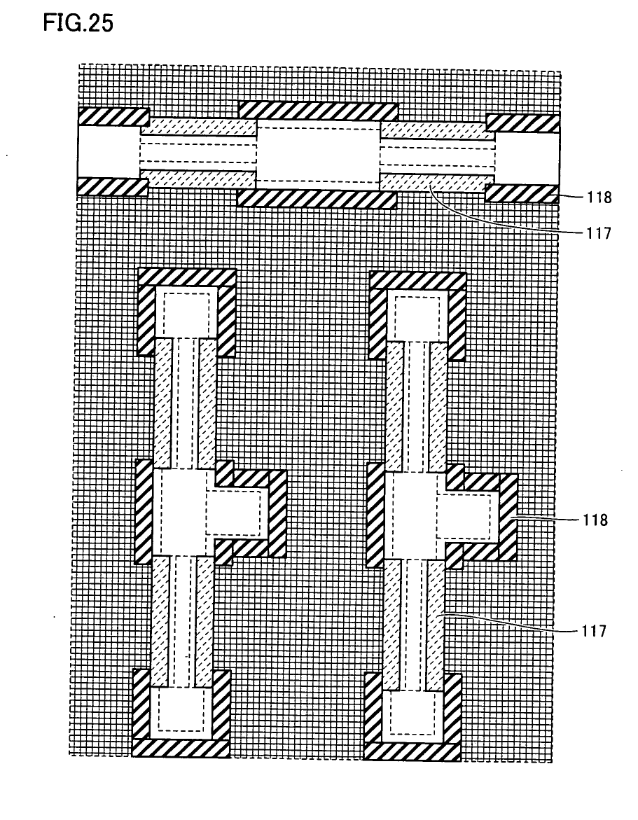

Thereafter, all regions surrounding light-shielding portion 1, linear pattern 117 and pattern 118 described above are made to serve as in-phase semi-transmissive portion 2 (see FIG. 2) according to the technique in Embodiment 1. In other words, as described in Embodiment 1, fine light-shielding patterns are arranged at such a small pitch as not allowing resolution by applied projection exposure system, in all regions surrounding light-shielding portion 1, linear pattern 117 and pattern 118. Here, provided that a ratio of occupied area is set to a substantially constant value, the fine light-shielding pattern to be arranged does not necessarily have to be in a square shape, and may be in a rectangular shape or in any shape. In addition, so long as such a condition that the pitch is fine enough not to allow resolution by projection exposure system is satisfied, a pitch for arrangement does not need to be equal, depending on a position within the region. The mask pattern shown in FIG. 25 is thus obtained. The patterns are arranged as described above, so that all regions surrounding light-shielding portion 1, linear pattern 117 and pattern 118 can serve as in-phase semi-transmissive portion 2 (see FIG. 2) according to the technique in Embodiment 1.

The mask pattern (see FIG. 25) for applying the technique in Embodiment 1 is generated by generating and arranging the patterns that implement the mask, in accordance with the above-described procedure.

After the mask pattern is generated as described above, optical proximity correction (OPC) software, which is a common measure in the art, is used for fine adjustment of a position of a mask pattern edge.

As the method of generating the mask pattern in the present embodiment is carried out in the above-described manner, the mask pattern can automatically be generated from the design pattern layout of the device by using standard CAD software for layout design. Therefore, it is not necessary to manually generate the mask pattern and significant reduction in cost necessary for generating the mask pattern can be achieved.

### Embodiment 8

Referring to FIGS. 1, 6, 12, 16, and 26-28, a method of generating a mask pattern in Embodiment 8 of the present invention will be described. FIG. 16 shows a design pattern layout required in terms of device design. As shown in FIG. 16, the design pattern layout in this example includes fine isolated linear portion 115 that should be formed by applying the technique shown in Embodiments 1 to 3 and a portion other than fine isolated linear portion 115 that has a large dimension and does not necessarily require application of the technique shown in Embodiments 1 to 3. Fine isolated linear portion 115 corresponds to linear pattern 112 shown in FIG. 12.

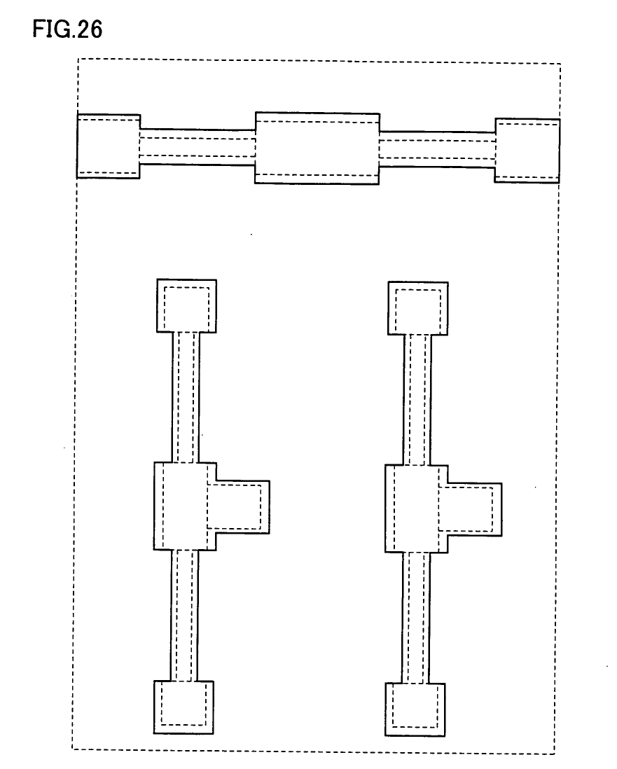

As a method of generating a mask pattern in the present embodiment, a method of generating a mask pattern different from Embodiment 6 when the technique in Embodiment 2 is applied will be described. Solely a fine linear geometric portion is extracted from the design pattern layout. A line width of the extracted portion is made larger to line width W2, and a geometry for center light-shielding linear portion 5h required for forming fine line patterns is created. Necessary resizing (dimension change) is performed also for the portion other than the fine linear geometric portion in the design pattern layout. Through the graphics processing above, a light-shielding pattern in a mask is generated as shown in FIG. 26. Center light-shielding linear portion 5h corresponds to that shown in FIG. 6 according to the technique in Embodiment 2.

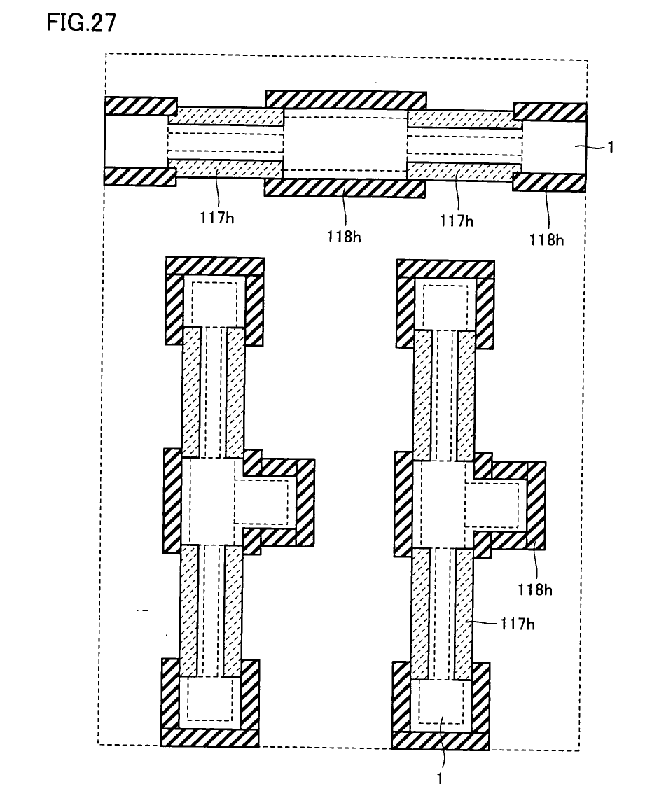

Thereafter, a linear pattern 117h having a length substantially equal to center light-shielding linear portion 5h and a width W1 in Embodiment 2 is created as a mask pattern corresponding to a pair of light-transmission opening patterns 4h (see FIG. 6) according to the technique in Embodiment 2. Then, a pattern 118 having a width close to W1 is arranged on an outer perimeter of a light-shielding geometry other than the fine linear geometric portion. The mask pattern shown in FIG. 27 is thus obtained.

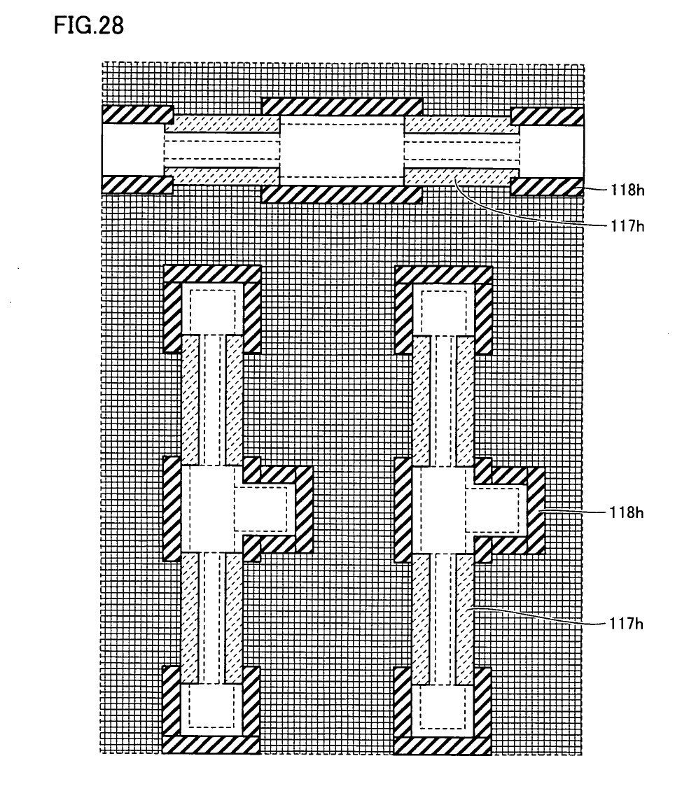

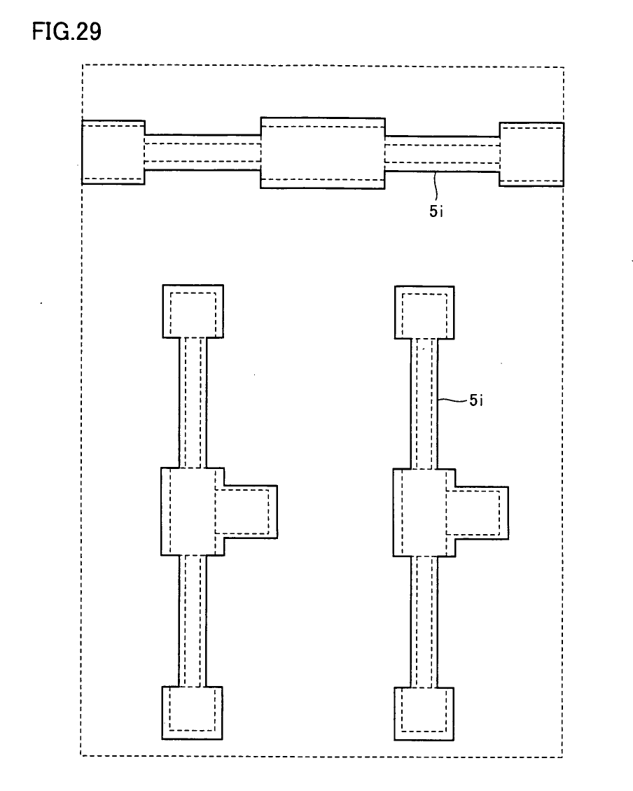

Thereafter, all regions surrounding light-shielding portion 1, linear pattern 117h and pattern 118h described above are made to serve as in-phase semi-transmissive portion 2h (see FIG. 6) according to the technique in Embodiment 2. In other words, as described in Embodiment 2, fine halftone phase shift patterns are arranged at such a small pitch as not allowing resolution by applied projection exposure system, in all regions surrounding light-shielding portion 1, linear pattern 117h and pattern 118h. Here, provided that a ratio of occupied area is set to a substantially constant value, the fine halftone phase shift pattern to be arranged does not necessarily have to be in a square shape, and may be in a rectangular shape or in any shape. In addition, so long as such a condition that the pitch is fine enough not to allow resolution by projection exposure system, a pitch for arrangement does not need to be equal, depending on a position within the region. The mask pattern shown in FIG. 28 is thus obtained. The patterns are arranged as described above, so that all regions surrounding light-shielding portion 1, linear pattern 117h and pattern 118h can serve as in-phase semi-transmissive portion 2h (see FIG. 6) according to the technique in Embodiment 2.

The mask pattern (see FIG. 28) for applying the technique in Embodiment 2 is generated by generating and arranging the patterns that implement the mask, in accordance with the above-described procedure.

After the mask pattern is generated as described above, optical proximity correction (OPC) software, which is a common measure in the art, is used for fine adjustment of a position of a mask pattern edge.

As the method of generating the mask pattern in the present embodiment is carried out in the above-described manner, the mask pattern can automatically be generated from the design pattern layout of the device by using standard CAD software for layout design. Therefore, it is not necessary to manually generate the mask pattern and significant reduction in cost necessary for generating the mask pattern can be achieved.

### Embodiment 9

Referring to FIGS. 1, 9, 12, 16, and 29-31, a method of generating a mask pattern in Embodiment 7 of the present invention will be described. FIG. 16 shows a design pattern layout required in terms of device design. As shown in FIG. 16, the design pattern layout in this example includes fine isolated linear portion 115 that should be formed by applying the technique shown in Embodiments 1 to 3 and a portion other than fine isolated linear portion 115 that has a large dimension and does not necessarily require application of the technique shown in Embodiments 1 to 3. Fine isolated linear portion 115 corresponds to linear pattern 112 shown in FIG. 12.

As a method of generating a mask pattern in the present embodiment, an exemplary method of generating a mask pattern when the technique in Embodiment 3 is applied will be described. Solely a fine linear geometric portion is extracted from the design pattern layout. A line width of the extracted portion is made larger to line width W2, and a geometry for center light-shielding linear portion 5i required for forming fine line patterns is created. Necessary resizing (dimension change) is performed also for the portion other than the fine linear geometric portion in the design pattern layout. Through the graphics processing above, a light-shielding pattern in a mask is generated as shown in FIG. 29. Center light-shielding linear portion 5i corresponds to that shown in FIG. 9 according to the technique in Embodiment 3.

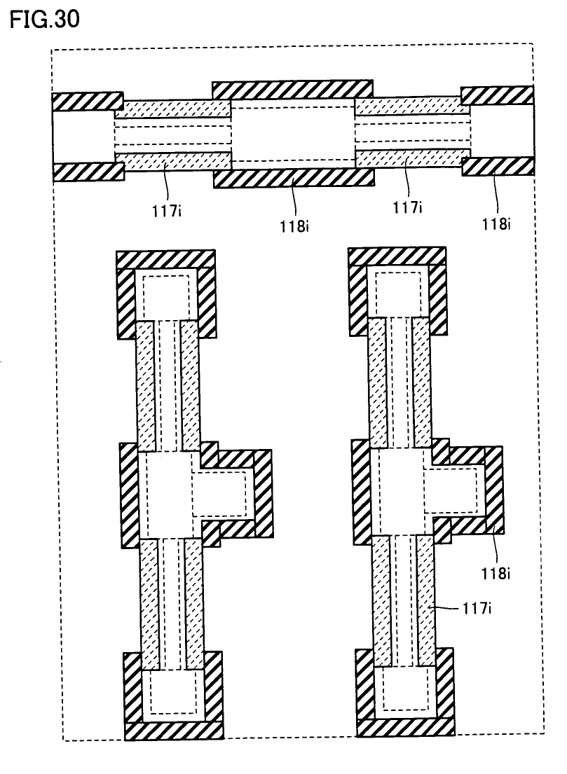

Thereafter, a linear pattern 117i having a length substantially equal to center light-shielding linear portion 5i and a width W1 in Embodiment 3 is created as a mask pattern corresponding to a pair of light-transmission opening patterns 4i (see FIG. 9) according to the technique in Embodiment 3. Then, a pattern 118i having a width close to W1 is arranged on an outer perimeter of a light-shielding geometry other than the fine linear geometric portion. The mask pattern shown in FIG. 30 is thus obtained. The region obtained by combining linear pattern 117i and pattern 118i serves as a portion formed in the quartz substrate to a necessary depth in manufacturing a mask, as shown in FIG. 9.

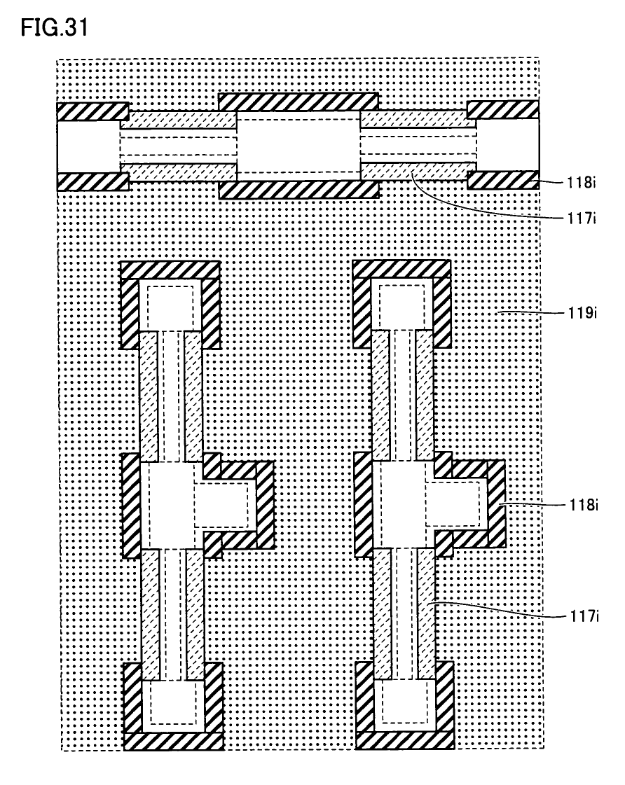

Thereafter, all regions surrounding light-shielding portion 1, linear pattern 117i and pattern 118i described above are made to serve as in-phase seri-transmissive portion 2i (see FIG. 9) according to the technique in Embodiment 3. In other words, as described in Embodiment 3, a halftone phase shift film forming portion 119i attaining transmittance of 20% is arranged in all regions surrounding light-shielding portion 1, linear pattern 117i and pattern 118i. The mask pattern shown in FIG. 31 is thus obtained.

The mask pattern (see FIG. 31) for applying the technique in Embodiment 3 is generated by generating and arranging the patterns that implement the mask, in accordance with the above-described procedure.

After the mask pattern is generated as described above, optical proximity correction (OPC) software, which is a common measure in the art, is used for fine adjustment of a position of a mask pattern edge.

As the method of generating the mask pattern in the present embodiment is carried out in the above-described manner, the mask pattern can automatically be generated from the design pattern layout of the device by using standard CAD software for layout design. Therefore, it is not necessary to manually generate the mask pattern and significant reduction in cost necessary for generating the mask pattern can be achieved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A photomask comprising:
a pair of light-transmission opening patterns extending in parallel and each having a substantially identical line width with a center light-shielding linear portion extending linearly therebetween; and
semi-transmissive regions arranged to sandwich said pair of light-transmission opening patterns from opposing sides in a direction of width; wherein
said semi-transmissive region has such a characteristic that light transmitted through said semi-transmissive region is in phase with light transmitted through said light-transmission opening pattern, and
said semi-transmissive region is implemented by patterns arranged at such a small pitch as not resolved by illumination of said light.

2. The photomask according to claim 1, wherein
said semi-transmissive region is implemented in such a manner that basic patterns are repeated at a pitch p which satisfies relation of p<0.5×λ/NA, where λ represents a wavelength of projected light and NA represents a numerical aperture of said semi-transmissive region.

3. The photomask according to claim 2, wherein
said basic pattern is implemented by a light-shielding portion or a semi-transmissive portion substantially in a rectangular or linear shape.

4. The photomask according to claim 2, wherein
said basic pattern is implemented by an opening portion substantially in a rectangular shape formed in a light-shielding portion or in a semi-transmissive portion.

5. The photomask according to claim 2, wherein
said light-transmission opening pattern has a width W1 which satisfies relation of 0.25×λ/NA<W1<0.75×λ/NA.

6. The photomask according to claim 2, wherein
said center light-shielding linear portion has a width W2 which satisfies relation of W2>0.25×λ/NA.

7. The photomask according to claim 2, wherein
an interval W3 between said light-transmission opening pattern and adjacent another pair of light-transmission opening patterns satisfies relation of W3>0.75×(λ/NA).

8. The photomask according to claim 2, wherein
said light-transmission opening pattern has a length L which satisfies relation of L>1.3×(λ/NA).

9. The photomask according to claim 2, wherein
said semi-transmissive region has a width W4 which satisfies relation of W4>0.75×(λ/NA).

10. The photomask according to claim 1, wherein
said semi-transmissive region has transmittance of light from at least 10% to at most 50%.

11. A photomask comprising:
a pair of light-transmission opening patterns extending in parallel and each having a substantially identical line width with a light-shielding portion extending linearly therebetween; and
semi-transmissive regions arranged to sandwich said light-transmission opening patterns from opposing sides in a direction of width; wherein
said light-transmission opening patterns and said semi-transmissive regions are provided on a transparent substrate, said light-transmission opening pattern is implemented as a recessed portion formed in a surface of said transparent substrate, and said semi-transmissive region is structured such that the surface of said transparent substrate is covered with a phase shift film, and
relation between a depth of said recessed portion and a thickness and a material for said phase shift film is such that light transmitted through said semi-transmissive region is in phase with light transmitted through said light-transmission opening pattern.

12. The photomask according to claim 11, wherein
said phase shift film has transmittance of light from at least 10% to at most 50%.

13. A method of manufacturing a semiconductor device, comprising the steps of:
partially exposing a photoresist layer by irradiating said photoresist layer formed on a surface of an object in advance through the photomask of claim 1 and projecting a desired pattern;
developing exposed said photoresist layer to pattern said photoresist layer; and
etching said object using patterned said photoresist layer as a mask, to form a linear pattern.

14. The method of manufacturing a semiconductor device according to claim 13, wherein
energy of light emitted through a main opening portion of said photomask in said step of exposing is of magnitude at least three times to at most twenty times as great as exposure energy to turn said photoresist layer from soluble to insoluble in a developer or exposure energy to turn said photoresist layer from insoluble to soluble in the developer.

15. The method of manufacturing a semiconductor device according to claim 13, wherein
off-axis illumination is employed in said step of exposing, in which relation of 0.5<(sin θ)/(NAₒ×R)<0.9 is satisfied where θ represents an incident angle of illumination light on said photomask, NAₒ represents a numerical aperture of projection optical system, and 1/R represents a reduction projection scale.

16. The method of manufacturing a semiconductor device according to claim 13, wherein
said off-axis illumination is realized by crosspole illumination in which a direction of incidence is in parallel to X, Y coordinate axes of said photomask.

17. The method of manufacturing a semiconductor device according to claim 13, wherein
said off-axis illumination is realized by quadrupole illumination in which a direction of incidence is at an angle of 45° to X, Y coordinate axes of said photomask.

18. The method of manufacturing a semiconductor device according to claim 13, wherein
said off-axis illumination is realized by annular illumination in which light enters a plane of said photomask isotropically around 360°.

19. A method of generating a mask pattern, comprising the steps of:
extracting a fine line pattern geometric portion from a design pattern layout;
implementing a part of a light-shielding pattern in a mask by adjusting said fine line pattern geometric portion such that said fine line pattern geometric portion serves as a masking dark line having a line width W2 which satisfies relation of 0.25<W2/(λ/NA), where λ represents a wavelength of exposure light and NA represents a numerical aperture of projection optical system;
arranging a pair of light-transmission opening patterns each having a line width W1 which satisfies relation of 0.25<W1/(λ/NA)<0.75, so as to sandwich said masking dark line having line width W2; and
arranging a semi-transmissive region through which light transmits at transmittance of at least 10% to at most 50%, the transmitted light being in phase with light transmitted through said light-transmission opening pattern, outside said pair of light-transmission opening patterns such that width W4 satisfies relation of 0.50<W4/(λ/NA).

20. The method of generating a mask pattern according to claim 19, wherein
a pattern having a spatial period smaller than λ/(2×NA) is arranged as a pattern serving as said semi-transmissive region, through which diffracted light except for zero-order diffracted light cannot pass in a projection exposure system.

21. A method of generating a mask pattern, comprising the steps of:
extracting a fine line pattern geometric portion from a design pattern layout;
implementing a first light-shielding pattern in a mask by adjusting said fine line pattern geometric portion such that said fine line pattern geometric portion serves as a masking dark line having a line width W2 which satisfies relation of 0.25<W2/(λ/NA), where λ represents a wavelength of exposure light and NA represents a numerical aperture of projection optical system;
implementing a second light-shielding pattern in the mask by resizing a pattern other than said fine line pattern geometric portion in said design pattern layout;
arranging a pair of first light-transmission opening patterns each having a line width W1 which satisfies relation of 0.25<W1/(λ/NA)<0.75, so as to sandwich said first light-shielding pattern;
arranging a second light-transmission opening pattern outside a side of said second light-shielding pattern such that the second light-transmission opening pattern has a substantially constant width; and
arranging a pattern serving as a semi-transmissive region through which light transmits at transmittance of at least 10% to at most 50%, the transmitted light being in phase with light transmitted through said light-transmission opening pattern, in a region excluding said first and second light-shielding patterns and said first and second light-transmission opening patterns from all mask regions.

22. The method of generating a mask pattern according to claim 21, wherein
an element pattern having a spatial period smaller than λ/(2×NA) is arranged as a pattern serving as said semi-transmissive region, through which diffracted light except for zero-order diffracted light cannot pass in a projection exposure system.
